(19) United States
(12) Patent Application Publication
(10) Pub. No.: US 2024/0276791 A1
(43) Pub. Date: Aug. 15, 2024

(54) LIGHT-EMITTING ELEMENT, DISPLAY DEVICE, AND METHOD FOR MANUFACTURING LIGHT-EMITTING ELEMENT

(71) Applicant: Sharp Display Technology Corporation, Kameyama City, Mie (JP)

(72) Inventor: Takayuki NAKA, Kameyama City, Mie (JP)

(21) Appl. No.: 18/681,046

(22) PCT Filed: Oct. 1, 2021
(86) PCT No.: PCT/JP2021/036444

§ 371 Date: Feb. 3, 2024

(51) Int. Cl. H10K 59/122; H10K 50/115; H10K 59/12

(52) U.S. Cl. CPC H10K 59/122; H10K 59/1201; H10K 50/115

(57) ABSTRACT

In a light-emitting element according to the present disclosure, if, as to thicknesses in a direction perpendicular to an upper surface of an anode, a hole transport layer has: a thickness D1 above a center of an anode; and a thickness D2 above a boundary line between the upper surface of the anode and a side surface of the bank, a relationship of D1<D2 holds.

### TECHNICAL FIELD

The disclosure relates to a light-emitting element, a display device, and a method for manufacturing the light-emitting element.

### BACKGROUND ART

Electroluminescent elements are required to have smaller effective light emission areas so that display devices including the electroluminescent elements further increase in definition. The electroluminescent elements include, for example, quantum-dot light-emitting diodes (QLEDs) or organic light-emitting diodes (OLEDs).

Patent Documents 1 to 3 disclose OLEDs.

### CITATION LIST

### Patent Literature

[Patent Document 1] International Publication No. WO/2012/017492A1 (Published on Feb. 9, 2012)
[Patent Document 2] Japanese Unexamined Patent Application Publication No. 2012-048906 (Published on Mar. 8, 2012)
[Patent Document 3] Japanese Unexamined Patent Application Publication No. 2013-073820 (Published on Apr. 22, 2013)

### SUMMARY

### Technical Problems

In a known electroluminescent element, a light-emitting layer tends to emit intense light (i.e., abnormal light) in a ring shape along an outline of an opening of an edge cover. This emission of abnormal light makes an effective light-emitting region of the electroluminescent element large in appearance.

Electroluminescent elements are required to have the light-emitting regions reduced in area.

### Solution to Problems

A light-emitting element according to an aspect of the present disclosure includes: an anode; a bank at least partially adjacent to, or disposed above, the anode; a hole injection layer formed at least partially on an upper surface of the anode and a side surface of the bank; a hole transport layer formed above the hole injection layer; a light-emitting layer formed above the hole transport layer; and a cathode formed above the light-emitting layer. If, as to thicknesses in a direction perpendicular to the upper surface of the anode, the hole transport layer has: a thickness D1 above a center of the anode; and a thickness D2 above a boundary line between the upper surface of the anode and the side surface of the bank, a relationship of D1<D2 holds.

In a light-emitting element according to an aspect of the present disclosure, the bank may have a tilt angle T, and a relationship of D1<D2*cos T may hold. Note that, in the present disclosure, the symbol “*” is an operation symbol denoting integration.

In a light-emitting element according to an aspect of the present disclosure, the tilt angle T may have a relationship of 0°<T<50°.

In a light-emitting element according to an aspect of the present disclosure, if, as to a thickness in the direction perpendicular to the upper surface of the anode, the hole transport layer has a thickness D3 1 μm inward away from above the boundary line of the hole transport layer, a relationship of D1*2.3<D3 may hold.

In a light-emitting element according to an aspect of the present disclosure, the hole injection layer may contain an inorganic hole transport material.

In a light-emitting element according to an aspect of the present disclosure, the inorganic hole transport material may be a metal oxide.

In a light-emitting element according to an aspect of the present disclosure, the hole injection layer may have an electrical resistivity of 1*10⁶ Ωcm or more.

In a light-emitting element according to an aspect of the present disclosure, the light-emitting layer may contain quantum dots.

A light-emitting element according to an aspect of the present disclosure includes: a first electrode; a bank at least partially either adjacent to the first electrode, or disposed above the first electrode; a first layer containing an inorganic hole transport material, and formed at least partially on an upper surface of the first electrode and a side surface of the bank; a second layer containing an organic hole transport material, and formed above the first layer; a light-emitting layer formed above the second layer; and a second electrode formed above the light-emitting layer. If, as to thicknesses in a direction perpendicular to the upper surface of the first electrode, the second layer has: a thickness D1 above a center of the first electrode; and a thickness D2 above a boundary line between the upper surface of the first electrode and the side surface of the bank, a relationship of D1<D2 holds.

A display device according to an aspect of the present disclosure includes the light-emitting element.

A display device according to an aspect of the present disclosure includes the light-emitting element. Each of the hole injection layer and the hole transport layer is formed in common to the plurality of light-emitting elements.

A method for manufacturing a light-emitting element according to an aspect of the present disclosure includes steps of: (a) forming an anode; (b) forming a bank at least partially adjacent to, or disposed above, the anode; (c) forming a hole injection layer at least partially on an upper surface of the anode and a side surface of the bank; (d) forming a hole transport layer above the hole injection layer; (e) forming a light-emitting layer above the hole transport layer; and (f) forming a cathode above the light-emitting layer. If, as to thicknesses in a direction perpendicular to the upper surface of the anode, the hole transport layer has: a thickness D1 above a center of the anode; and a thickness D2 above a boundary line between the upper surface of the anode and the side surface of the bank, step (d) involves forming the hole transport layer so that a relationship of D1<D2 holds.

In a method for manufacturing the light-emitting element according to an aspect of the present disclosure, step (d) may include steps of:
(g) applying a solution to the hole injection layer; and (h) solidifying the solution. At step (g), the solution may make contact with the hole injection layer at an angle of smaller than 90°.

In a method for manufacturing the light-emitting element according to an aspect of the present disclosure, the solution may be prepared so that a solute of the solution has a volume density of 6 mg/ml or more.

In a method for manufacturing the light-emitting element according to an aspect of the present disclosure, the solution may be prepared so that a solute of the solution has a volume density of 8 mg/ml or more.

In a method for manufacturing the light-emitting element according to an aspect of the present disclosure, at step (g), the solution may be applied by spin coating at a rotation speed of 2000 rpm or less.

In a method for manufacturing the light-emitting element according to an aspect of the present disclosure, at step (g), the solution may be applied by spin coating at a rotation speed of 1000 rpm or less.

### Advantageous Effects of Disclosure

Thanks to an aspect of the present disclosure, a light-emitting element can have an effective light-emitting region reduced in size.

### BRIEF DESCRIPTION OF DRAWINGS

FIG. 1 is a plan view of an exemplary schematic configuration of a display device according to an embodiment of the present disclosure.

FIG. 2 is a plan view of an exemplary schematic configuration of a display region illustrated in FIG. 1.

FIG. 3 is a cross-sectional view of an exemplary schematic configuration of the display region illustrated in FIG. 1.

FIG. 4 is a cross-sectional view of a thickness of a hole transport layer illustrated in FIG. 3.

FIG. 5 is a schematic diagram illustrating a tilt angle of an edge cover illustrated in FIG. 3.

FIG. 6 is a schematic flowchart showing an example of a method for manufacturing the display device according to an embodiment of the present disclosure.

FIG. 7 is a cross-sectional view of a modification of a schematic configuration of the light-emitting element according to an embodiment of present disclosure.

FIG. 8 is a cross-sectional view of an exemplary schematic configuration of a display region of the display device according to an embodiment of the present disclosure.

FIG. 9 is a cross-sectional view of an exemplary schematic configuration of the display region of the display device according to an embodiment of the present disclosure.

FIG. 10 is a graph showing results of measuring voltage and luminance in light-emitting element layers of some of examples in the present disclosure.

FIG. 11 is a photograph taken when a light-emitting element layer of an example according to an embodiment of the present disclosure emits light.

### DESCRIPTION OF EMBODIMENTS

### First Embodiment

### Outline of Display Device

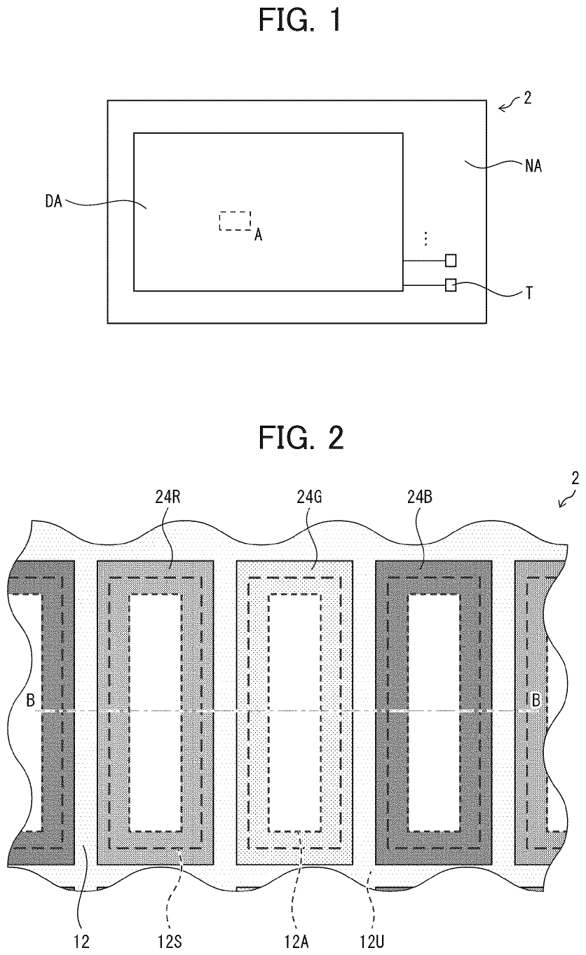

FIG. 1 is a plan view of an exemplary schematic configuration of a display device 2 according to an embodiment of the present disclosure.

As illustrated in FIG. 1, the display device 2 according to present disclosure includes: a display region DA that releases light emitted from light-emitting elements to display an image; and a picture-frame region NA surrounding the display region DA. The light-emitting elements will be described later. The picture-frame region NA includes terminals T formed to receive signals for driving the light-emitting elements of the display device 2.

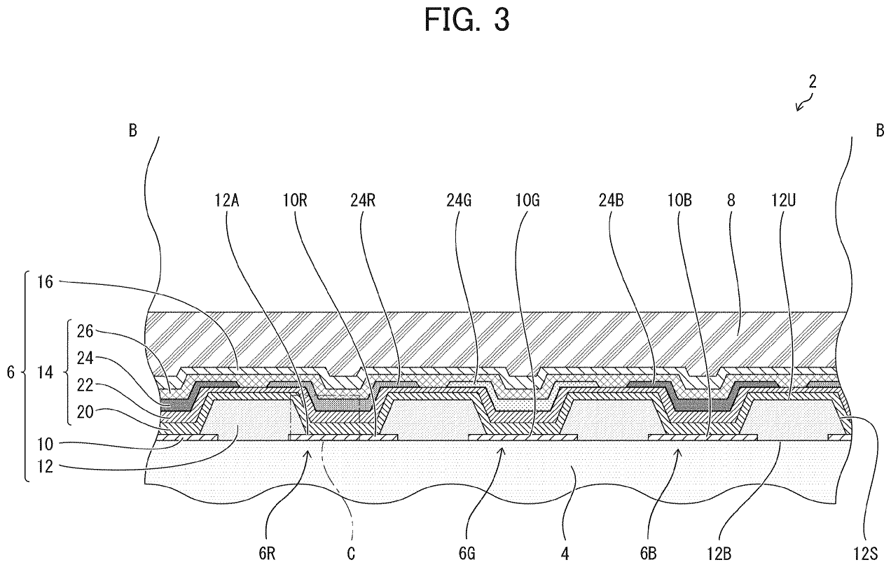

FIG. 2 is a plan view of an exemplary schematic configuration of the display region DA illustrated in FIG. 1. FIG. 2 corresponds to an enlarged plan view of a region A in FIG. 1. Note that, FIG. 2 omits the other constituent features in order to show a positional relationship between an edge cover 12 (a bank) and a light-emitting layer 24. The edge cover 12 and the light-emitting layer 24 will be described later.

FIG. 3 is a cross-sectional view of an exemplary schematic configuration of the display region DA illustrated in FIG. 1. FIG. 3 corresponds to a cross-sectional view taken along line B-B in FIG. 2.

In the display region DA, the display device 2 according to this embodiment includes a plurality of electroluminescent elements. Among the plurality of electroluminescent elements included in the display device 2, FIGS. 2 and 3 illustrate a red light-emitting element 6R, a green light-emitting element 6G, and a blue light-emitting element 6B. In the present disclosure, unless otherwise specified, the term “light-emitting element” refers to any one of the red light-emitting element 6R, the green light-emitting element 6G, or the blue light-emitting element 6B.

As illustrated in FIG. 3, the display device 2 includes: a substrate 4; a light-emitting element layer 6 above the substrate 4; and a sealing layer 8 covering the light-emitting element layer 6.

### Substrate

The substrate 4 includes a support substrate. The substrate 4 includes a thin-film transistor layer (a TFT layer) in which circuit elements such as thin-film transistors (TFTs) are provided on the support substrate. The substrate 4 may further include an additional constituent feature such as a barrier layer. The barrier layer keeps such objects as water and oxygen from entering the light-emitting element layer 6 from outside the support substrate.

The support substrate may be either an inflexible substrate made of quartz or glass, or a flexible substrate made of a resin film or a resin sheet. The quartz substrate and the glass substrate are preferable because such substrates sufficiently transmit light and block gas. In addition, from a viewpoint of light transmittance and gas blockage, the resin film is preferably made of: methacrylic resins represented by polyethylene methacrylate (PMMA); polyester resins represented by polyethylene terephthalate (PET), polyethylene naphthalate (PEN), and polybutylene naphthalate (PBN); and polycarbonate resins.

### Light-Emitting Element Layer

The light-emitting element layer 6 is provided with light-emitting elements.

The light-emitting element layer 6 includes: an anode 10 (a first electrode); an edge cover 12; an active layer 14; and a cathode 16 (a second electrode), all of which are sequentially provided from toward the substrate 4. The active layer 14 includes: a hole injection layer 20 (a first layer); a hole transport layer 22 (a second layer); a light-emitting layer 24; and an electron transport layer 26, all of which are sequentially provided from toward the anode 10. The active layer 14 is also referred to as an electroluminescent layer (an EL layer).

In the present disclosure, the direction from the light-emitting layer 24 toward the anode 10 of the light-emitting element layer 6 is referred to as a “downward direction”, and the direction from the light-emitting layer 24 toward the cathode 16 of the light-emitting element layer 6 is referred to as an “upward direction”.

Here, the anode 10 is formed individually for each of the light-emitting elements. The anode 10 is shaped into an island shape and provided for each light-emitting element, that is, for each subpixel. The anode 10 is also referred to as a “pixel electrode”. The anode 10 includes: an anode 10R for the red light-emitting element 6R; an anode 10G for the green light-emitting element 6G; and an anode 10B for the blue light-emitting element 6B. Whereas, each of the hole injection layer 20, the hole transport layer 22, the electron transport layer 26, and the cathode 16 is formed in common to the plurality of light-emitting elements. The cathode 16 is also referred to as a “common electrode”.

The edge cover 12 may be individually formed for each of the light-emitting elements; however, the edge cover 12 is formed preferably integrally for the plurality of light-emitting elements as illustrated in FIG. 2 in order to enhance the definition of the display device 2. The edge cover 12 of this embodiment is at least partially disposed above the anode 10. However, the edge cover 12 does not necessarily have to be partially disposed above the anode 10. Specifically, the edge cover 12 may be partially in contact with an end surface of the anode 10; however, the edge cover 12 does not have to be disposed above the anode 10. Furthermore, as seen in this embodiment, the edge cover 12 may be formed to at least partially overlap with the end face of the anode 10 when viewed from the top. The edge cover 12 is preferably formed to cover a portion near the end face (i.e., an “edge”) of the anode 10 when viewed from the top. The edge cover 12 has an opening 12A. The opening 12A exposes an upper surface of the anode 10. Note that the term “exposed” describes shapes of the edge cover 12 and the anode 10 in relationships between the two layers alone. As will be described below, other layers are finally formed in the exposed portion. Hereinafter, unless otherwise specified, the term “exposed” describes the shapes of the edge cover 12 and the anode 10 in relationships between the two layers. The edge cover 12 has: a bottom surface 12B toward the substrate 4; an upper surface 12U toward the sealing layer 8; and a side surface 12S between the bottom surface 12B and the upper surface 12U. The side surface 12S, including a tilted side surface, is also referred to as a “slope”. Note that the side surface and the slope do not have to be planar surfaces. Each of the side surface and the slope may include a plurality of planar surfaces, a curved surface, or asperities.

The edge cover 12 is formed between the light-emitting elements adjacent to each other, and electrically insulates the adjacent light-emitting elements from each other. Hence, the edge cover 12 divides the light-emitting element layer 6 into the red light-emitting element 6R, the green light-emitting element 6G, and the blue light-emitting element 6B. The edge cover 12 is also referred to as a “partition wall” or a “bank”.

The light-emitting layer 24 includes: a red light-emitting layer 24R that emits a red light; a green light-emitting layer 24G that emits a green light; and a blue light-emitting layer 24B that emits a blue light. The light-emitting layer 24 may be formed either individually for each light-emitting element, or in common to a plurality of light-emitting elements in the same color.

The light-emitting layer 24 is formed to cover at least the corresponding anode 10 exposed from the opening 12A of the edge cover 12. When the hole transport layer 22 and the electron transport layer 26 are in contact with each other either above or nearly above a region in which the anode 10 is exposed, a reactive current flows through the contact portion. The reactive current does not contribute to emission of light from the light-emitting layer 24. Hence, the light-emitting layer 24 preferably further covers a portion of the side surface 12S of the edge cover 12 (specifically, a portion close to the outline of the corresponding opening 12A). Furthermore, as illustrated in FIG. 2, the light-emitting layer 24 covers a wide range including the side surface 12S and the upper surface 12U of the edge cover 12. Such a feature can further reduce the reactive current. More specifically, for example, the light-emitting layer 24 entirely covers the side surface 12S, and partially covers the upper surface 12U, of the edge cover 12. Such a feature can further reduce the reactive current. Note that, in FIG. 2, a broken line denoting the side surface 12S is a boundary portion between the side surface 12S and the upper surface 12U of the edge cover 12.

Note that, in the configuration illustrated in FIG. 3, the hole transport layer 22 is in direct contact with the electron transport layer 26 above the upper surface 12U of the edge cover 12. Usually, a reactive current flows when the hole transport layer 22 and the electron transport layer 26 are in direct contact with each other; however, in the present disclosure, the direct contact is away from the region in which the anode 10 is exposed. That is why the reactive current is reduced. It is because a charge transport layer and/or a charge injection layer is significantly higher in electrical resistivity than ordinary metals and semiconductors. Because an electrical resistance value is large in a path from the anode 10 through the hole transport layer 22 and/or the electron transport layer 26 to the contact portion above the upper surface 12U of the edge cover 12, the present disclosure can reduce the reactive current running in the path to a negligible level, or even to substantially zero. In order to reduce a size of the contact portion above the upper surface 12U of the edge cover 12, the adjacent light-emitting layers 24 are preferably arranged at a small spacing.

Hence, in this embodiment, the red light-emitting element 6R includes: the anode 10R; the edge cover 12 covering the edge of the anode 10R and having the opening 12A expose the upper surface of the anode 10R; the hole injection layer 20 formed at least partially on the upper surface of the anode 10R and the side surface 12S of the edge cover 12; the red light-emitting layer 24R formed above the hole injection layer 20; the electron transport layer 26 formed above the red light-emitting layer 24R; and the cathode 16 formed above the electron transport layer 26. Note that the hole transport layer 22 may be provided between the hole injection layer 20 and the red light-emitting layer 24R.

Likewise, the green light-emitting element 6G includes: the anode 10G; the edge cover 12 covering the edge of the anode 10G and having the opening 12A expose the upper surface of the anode 10G; the hole injection layer 20 formed at least partially on the upper surface of the anode 10G and the side surface 12S of the edge cover 12; the green light-emitting layer 24G formed above the hole injection layer 20; the electron transport layer 26 formed above the green light-emitting layer 24G; and the cathode 16 formed above the electron transport layer 26. Note that the hole transport layer 22 may be provided between the hole injection layer 20 and the green light-emitting layer 24G.

Likewise, the blue light-emitting element 6B includes: the anode 10B; the edge cover 12 covering the edge of the anode 10B and having the opening 12A expose the upper surface of the anode 10B; the hole injection layer 20 formed at least partially on the upper surface of the anode 10B and the side surface 12S of the edge cover 12; the blue light-emitting layer 24B formed above the hole injection layer 20; the electron transport layer 26 formed above the blue light-emitting layer 24B; and the cathode 16 formed above the electron transport layer 26. Note that the hole transport layer 22 may be provided between the hole injection layer 20 and the blue light-emitting layer 24B.

In the present disclosure, the “blue light” has a center wavelength in a wavelength band of, for example, 400 nm or more and 500 nm or less. Furthermore, the “green light” has a center wavelength in a wavelength band of, for example, more than 500 nm and 600 nm or less. Moreover, the “red light” has a center wavelength in a wavelength band of, for example, more than 600 nm and 780 nm or less.

Note that the light-emitting element layer 6 according to this embodiment shall not be limited to the above configuration, and may further include an additional layer between the anode 10 and the cathode 16. For example, the light-emitting element layer 6 may further include an electron injection layer between the electron transport layer 26 and the cathode 16. Alternatively, the light-emitting element layer 6 may omit the electron transport layer 26. Furthermore, the light-emitting layer 24 may emit light in either two or fewer colors or four or more colors.

The anode 10 and the cathode 16 contain a conductive material. At least one of the anode 10 or the cathode 16 is a transparent electrode. If the display device 2 is a single-sided display, either the anode 10 or the cathode 16 whichever closer to the display surface is the transparent electrode and whichever farther from the display surface is a reflective electrode. If the display device 2 is a double-sided display, both the anode 10 and the cathode 16 are transparent electrodes. A transparent electrode can be formed of a light-transparent conductive material. A reflective electrode can be formed of a light-reflective conductive material. The reflective electrode can be formed of a multilayer stack made of a light-transparent conductive material and a light-reflective conductive material.

The light-transparent conductive material includes such materials as indium tin oxide (ITO), indium zinc oxide (IZO), tin oxide (SnO₂), and fluorine-doped tin oxide (FTO). Because these materials are highly transparent to visible light, the light-emitting elements improve in light emission efficiency. The light-reflective conductive material may include such materials as aluminum (Al), silver (Ag), copper (Cu), and gold (Au). Because these materials are highly reflective to visible light, the light-emitting elements improve in light emission efficiency. Note that if the light-reflective conductive material is formed thin, the material can be consequently used as a light-transparent conductive material.

The anode 10 supplies the light-emitting layer 24 with holes, and the cathode 16 supplies the light-emitting layer 24 with electrons. The anode 10 is provided to face the cathode 16.

The hole injection layer 20 contains a material capable of transporting the holes. The hole injection layer 20 has a function of injecting the holes from the anode 10 into either the hole transport layer 22 or the light-emitting layer 24. The hole transport layer 22 contains a material capable of transporting the holes, and has a function of transporting the holes from either the hole injection layer 20 or the anode 10 into the light-emitting layer 24. Note that at least one of the hole injection layer 20 or the hole transport layer 22 preferably has a function of blocking the transportation of the electrons from the light-emitting layer 24 to the anode 10.

The hole injection layer 20 preferably contains a hole transporting material higher in electrical resistivity than polyethylene dioxythiophene (PEDOT: PSS) doped with polystyrene sulphonate. Specifically, the hole injection layer 20 preferably contains a hole transporting material having an electrical resistivity of 1*10⁶ Ωcm or more. This is because, if the electrical resistivity of the hole injection layer 20 is excessively low, the holes flow in the hole injection layer 20 along the upper surface of the anode 10 and the side surface 12S of the edge cover 12, which could increase the effective light-emitting region of the light-emitting element. Inorganic hole transport materials tend to be higher in electrical resistance than organic hole transport materials. Furthermore, inorganic materials are chemically more stable than organic materials. Hence, the hole injection layer 20 preferably contains an inorganic hole transport material. Moreover, the inorganic hole transport materials are preferably metal oxides. In this case, the chemical stability is further enhanced.

In the present disclosure, the symbol “*” is an operation symbol denoting integration.

Examples of the hole transport material suitable for the hole injection layer 20 include materials containing one or more selected from the group consisting of oxides, nitrides, or carbides containing any one or more of Zn, Cr, Ni, Ti, Nb, Al, Si, Mg, Ta, Hf, Zr, Y, La, Sr, and W. Among these materials, the inorganic hole transport material is preferably an oxide containing any one or more of Zn, Cr, Ni, Ti, Nb, Al, Si, Mg, Ta, Hf, Zr, Y, La, and Sr, and more preferably, at least one selected from NiO, MgO, MgNiO, LaNiO₃, CuO, and Cu₂O. Furthermore, examples of a suitable hole transport material include CuSCN; that is, a material in which a CN group, an SCN group, and a SeCN group are bonded to metal. These materials may be nanoparticles.

In a region corresponding to the opening 12A of the edge cover 12, the hole injection layer 20 has a minimum thickness of preferably 10 nm or more and a maximum thickness of preferably 150 nm or less. This is because, if the thickness is less than 10 nm, the hole injection layer 20 might not be able to transport sufficient holes. Furthermore, if the thickness is more than 150 nm, the hole injection layer 20 might develop a crack at the manufacturing step. The crack could reduce efficiency in injecting the holes from the hole injection layer 20 into the hole transport layer 22.

The hole injection layer 20 may have a surface provided with a self-assembled monolayer (SAM). The SAM can reduce a drive voltage of the light-emitting element.

The hole transport layer 22 preferably contains an organic hole transporting material higher in electrical resistivity than polyethylene dioxythiophene (PEDOT: PSS) doped with polystyrene sulphonate, and, more preferably, contains an organic hole transporting material having an electrical resistivity of 1*10⁶ Ωcm or more. This is because, if the electrical resistivity of the hole transport layer 22 is excessively low, the holes flow in the hole transport layer 22 in a direction in parallel with the upper surface of the anode 10, which would increase the effective light-emitting region of the light-emitting element. A preferable organic hole transport material can be appropriately selected from materials typically used in the field. Examples of the materials include: such materials as 4,4′,4″-tris(9-carbazolyl)triphenylamine (TCTA), 4,4′-bis[N-(1-naphthyl)-N-phenyl-amino]biphenyl (NPB), zinc phthalocyanine (ZnPC), di[4-(N,N-ditolylamino)phenyl]cyclohexane (TAPC), 4,4′-bis(carbazol-9-yl)biphenyl (CBP), 2,3,6,7,10,11-hexacyano-1,4,5,8,9,12-hexaazatriphenylene (HATCN); poly(N-vinylcarbazole) (PVK); poly(2,7-(9,9-di-n-octylfluorene)-(1,4-phenylene((4-sec-butylphenyl)imino)-1,4-phenylene (TFB); and a poly(triphenylamine) derivative (Poly-TPD). Among these materials, preferable materials include a tetracyano compound such as TFB, a carbazole derivative such as PVK, and a triarylamine derivative such as Poly-TPD.

In a region corresponding to the opening 12A of the edge cover 12, the hole transport layer 22 has a minimum thickness of preferably 10 nm or more and a maximum thickness of preferably 100 nm or less. This is because, if the thickness is less than 10 nm, the hole transport layer 22 might not be able to transport sufficient holes. Furthermore, if the thickness is more than 100 nm, the drive voltage of the light-emitting element rises.

The electron transport layer 26 contains a material capable of transporting electrons, and has a function of transporting the electrons from the cathode 16 to the light-emitting layer 24. The electron transport layer 26 preferably has a function of blocking the transportation of holes from the light-emitting layer 24 to the cathode 16.

Examples of an organic electron transport material suitable for the electron transport layer 26 include a compound and a complex containing one or more nitrogen-containing hetero rings such as oxadiazole rings, triazole rings, triazine rings, quinoline rings, phenanthroline rings, pyrimidine rings, pyridine rings, imidazole rings, and carbazole rings. Specifically, the examples include: 1,10-phenanthroline derivatives such as bathocuproine and bathophenanthroline; benzimidazole derivatives such as 1,3,5-tris(N-phenylbenzimidazol-2-yl)benzene (TPBI); metal complexes such as a tris(8-quinolinato) aluminium complex (Alq3), a bis(10-benzoquinolinolato) beryllium complex, an 8-hydroxyquinoline aluminum complex, and a bis(2-methyl-8-quinolinato)-4-phenylphenolate aluminum complex; and 4,4′-biscarbazolbiphenyl. Other specific examples include: an aromatic phosphine compound such as an aromatic boron compound, an aromatic silane compound, or phenyldi(1-pyrenyl)phosphine; and a nitrogen-containing hetero ring compound such as bathophenanthroline, bathocuproine, 2,2′,2″-(1,3,5-benzenetriyl)-tris(1-phenyl-1H-benzimidazole) (TPBI), or a triazine derivative.

Examples of the organic electron transport material suitable for the electron transport layer 26 additionally include a compound having a p-phenylene vinylene skeleton. Specific examples include a poly(p-phenylene vinylene) (PPV) compound such as poly (2-2′-ethyl-hexoxy)-5-methoxy-1,4-phenylene vinylene (POPh-PPV).

Furthermore, examples of an inorganic electron transport material suitable for the electron transport layer 26 include oxides containing one or more of Zn, Ni, Cr, Mg, Li, Ti, W, Mo, In, and Ga. Among these oxides, a preferable oxide is likely to have a shift toward the oxygen deficiency in accordance with the stoichiometric composition. Examples of the oxide include zinc oxide (ZnO), magnesium zinc oxide (MgZnO), titanium oxide (TiO₂), and strontium oxide (SrTiO₃). These materials may be nanoparticles.

The transparent electrode, the hole injection layer 20, the hole transport layer 22, and the electron transport layer 26 transmit light in a wavelength band to be used when the display device 2 displays an image.

The light-emitting layer 24 emits light. The holes from the anode 10 and the electrons from the cathode 16 recombine together so that a luminescent material is excited. When the excited luminescent material returns to the ground state, the light-emitting layer 24 emits light. When a voltage or a current is applied between the anode 10 and the cathode 16, the recombination occurs in the light-emitting layer 24 so that the light-emitting layer 24 emits light. The light-emitting layer 24 may contain, as a luminescent material, either quantum dots or an organic light-emitting material.

The quantum dots are dots each having a maximum width of 100 nm or less. A quantum dot may have any given shape as long as the maximum width of the quantum dot is within the above range. The shape of the quantum dot shall not be limited to a spherical shape (a circular cross-section). For example, the quantum dot may have a polygonal cross-section, a bar-like three dimensional shape, a branch-like three dimensional shape, or a three dimensional shape having asperities on the surface. Alternatively, the quantum dot may have a combination of those shapes. in the present disclosure, the quantum dots are, for example, fine semiconductor particles having a particle size of 100 nm or less, and may include: crystals of group II-VI semiconductor compounds such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe; crystals of group III-V semiconductor compounds such as GaAs, GaP, InN, InAs, InP, and InSb; and/or crystals of group IV semiconductor compounds such as Si and Ge. Furthermore, each of the quantum dots may have a core-shell structure in which the semiconductor crystals are used as a core, and the core is coated with a shell material having a high bandgap. Moreover, each quantum dot may have ligands adsorbed (coordinated) to a surface of the quantum dot. Note that the shell does not necessarily have to completely cover the core, and may be partially formed on the core. Furthermore, when the light-emitting layer 24 contains quantum dots and a compound to be ligands, the compound is deemed to be the ligands adsorbed (coordinated) to the surface of the quantum dots.

The edge cover 12 may contain such insulating materials as, for example, polyimide resins, acrylic resins, novolak resins, and fluorene resins. The edge cover 12 can be formed of a photosensitive resin material. The photosensitive resin material is patterned by photolithography to form the edge cover 12. The photosensitive resin may be either a negative resin or a positive resin.

The sealing layer 8 covers the light-emitting element layer 6, and seals each of the light-emitting elements included in the display device 2. The sealing layer 8 keeps such objects as oxygen and water from penetrating into such layers as the light-emitting element layer 6 out of the sealing layer 8 of the display device 2. The sealing layer may have a multilayer structure including, for example, an inorganic sealing film made of an inorganic material and an organic sealing film made of an organic material. The inorganic sealing film is formed by, for example, the CVD, and made of a silicon oxide film, a silicon nitride film, a silicon oxynitride film, or a multilayer film including these films. The organic sealing film is formed of, for example, an applicable resin material such as polyimide.

### Thickness of Hole Transport Layer

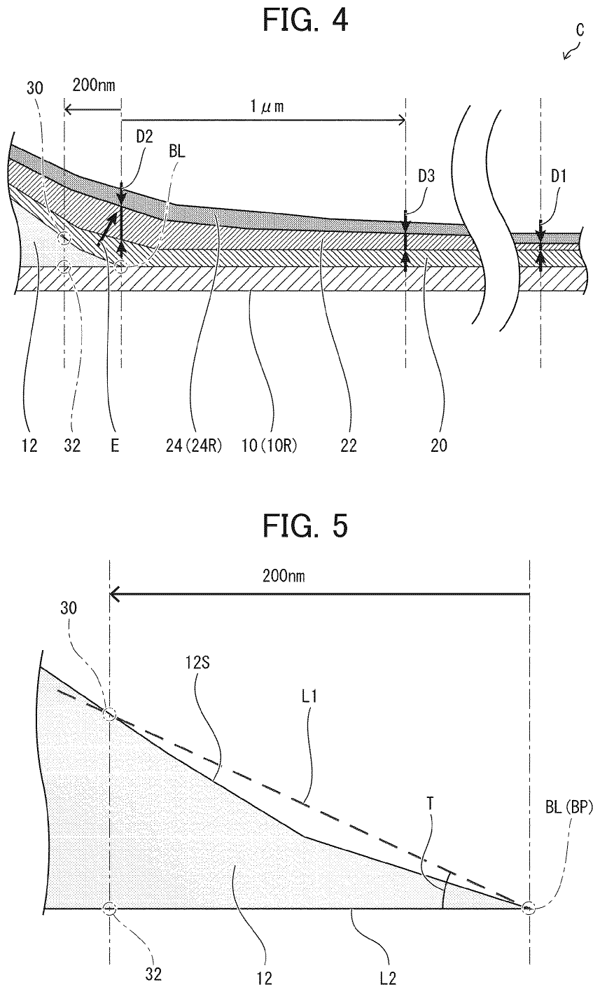

FIG. 4 is a cross-sectional view of a thickness of the hole transport layer 22 illustrated in FIG. 3. FIG. 4 corresponds to an enlarged cross-sectional view of a region C enclosed by a dash-dot line in FIG. 3. Note that, in order to focus on the description of the hole transport layer 22, FIG. 4 illustrates only the anode 10R, the edge cover 12, the hole injection layer 20, the hole transport layer 22, and the red light-emitting layer 24R, and omits illustrations of the other constituent features.

FIG. 5 is a schematic diagram illustrating a tilt angle T of the edge cover 12 illustrated in FIG. 3.

FIG. 4 shows that, as to the light-emitting element layer 6 according to the present disclosure, at least the hole transport layer 22 is not uniform in thickness. Furthermore, neither the hole injection layer 20 nor the red light-emitting layer 24R may be uniform in thickness, and the side surface 12S of the edge cover 12 may be non-flat.

As to a thickness in a direction perpendicular to the upper surface of the anode 10, the hole transport layer 22 has a thickness D1 above a center of the anode 10. Likewise, the hole transport layer 22 has: a thickness D2 above a boundary line BL between the anode 10 and the edge cover 12; and a thickness D3 positioned 1 μm inward away from the boundary line BL. The edge cover 12 has the tilt angle T.

Here, the center of the anode 10 is a center of the opening 12A of the edge cover 12. More specifically, the center of the opening 12A of the edge cover 12 is described as follows: when the edge cover 12 has a first portion and a second portion; that is, opposing end portions facing each other across any one of the layers included in the light-emitting element layer 6 above the anode 10, the center of the anode 10 is in a middle of a line segment connecting a lower end of the first portion toward the anode 10 and a lower end of the second portion toward the anode 10 in the cross-section across the first portion and the second portion. Note that the center of the opening 12A in the edge cover 12 can be different from the center of the upper surface of the anode 10. If the center of the opening 12A of the edge cover 12 is different from the center of the top surface of the anode 10, the center of the opening 12A in the edge cover 12 should be employed. The tilt angle T of the edge cover 12 is an angle between the side surface 12S and the upper surface of the anode 10 positioned outward from the boundary line BL (or between the side surface 12S and an imaginary surface obtained when the upper surface is extended.

As illustrated in FIG. 5, if the side surface 12S is non-flat, a flat imaginary surface close to the side surface 12S may be used instead of the side surface 12S. For example, in an outward position 200 nm away from the boundary line BL, a cross-section is assumed to include a normal line of the side surface 12S of the edge cover 12 and a normal line of the upper surface of the anode 10. On this cross-section, a boundary point BP is determined as a point on the boundary line BL. Furthermore, on this cross-section, an upper end point 30 is determined as a point found on the side surface 12S of the edge cover 12 and positioned outward 200 nm away from the boundary point BP, and a lower end portion 32 is determined as a point found on the upper surface of the anode 10 (or an imaginary surface obtained when the upper surface is extended) and positioned outward 200 nm away from the boundary point BP. Moreover, the tilt angle T is determined as an angle between a line segment L1 and a line segment L2. The line segment L1 connects the upper end point 30 and the boundary point BP together. The line segment L2 connects the lower end point 32 and the boundary point BP together.

In the present disclosure, unless otherwise specified, each of the terms “film thickness” and “thickness” refers to a thickness in a direction perpendicular to the upper surface of the anode 10R. Furthermore, the term “boundary line BL” refers to a boundary line between the upper surface of the anode 10 and the side surface 12S of the edge cover 12. The boundary line BL is also an outline of the opening 12A of the edge cover 12. Moreover, the statement “positioned inward from the boundary line BL (or from the boundary point BP)” means to be positioned toward the opening 12A of the edge cover 12 with respect to the boundary line BL (or to the boundary point BP). The statement “positioned outward from the boundary line BL (or from the boundary point BP)” means to be positioned toward the side surface 12S of the edge cover 12 with respect to the boundary line BL (or to the boundary point BP).

Here, the tilt angle T may hold a relationship of 0°<T<90°, 0°<T<70°, or 0°<T<40°. In order to reduce breakages of the light-emitting layer 24 and the cathode 16 caused by a level difference on the edge cover 12, the tilt angle T has a relationship of preferably 0°<T<50°.

For example, if the light-emitting layer 24 is broken because of a level difference on the light-emitting layer 24, the hole transport layer 22 and the electron transport layer 26 come into contact with each other either above or nearly above a region in which the anode 10 is exposed. Furthermore, a current flowing through the contact portion is a reactive current that does not contribute to emission of light from the light-emitting layer 24. Moreover, for example, when the cathode 16 is broken because of a level difference on the cathode 16, the cathode 16 suffers either insulation developed therein or a rise in electrical resistance. In order to prevent these phenomena, it is preferable to reduce the breakages caused by the level differences.

The present disclosure can keep the light-emitting layer 24 from emitting intense light (i.e., abnormal light) in a ring shape along the outline of the opening 12A of the edge cover 12 (i.e., along the boundary line BL). In order to reduce the emission of abnormal light, the thickness D2 of the hole transport layer 22 above the boundary line BL is preferably greater than a thickness of the hole transport layer 22 facing inside the opening 12A. This is because the thicker the hole transport layer 22 is, the longer the path is from the anode 10 to the light-emitting layer 24, and the larger the electric resistance value of the path is. Hence, the light-emitting layer 24 has difficulty in emitting light above or nearly above the boundary line BL.

Use of the meniscus effect can make the thickness D2 above the boundary line BL greater than the thickness D1. Here, the thinnest portion of the hole transport layer 22 inside the opening 12A is positioned in a center portion of the opening 12A; that is, a center portion of the anode 10. Hence, the thickness D2 of the hole transport layer 22 above the boundary line BL is preferably greater than the thickness D1 of the hole transport layer 22 in a center portion of the hole transport layer 22 (i.e., D1<D2).

The feature described above reduces the ring-shaped abnormal light emitted from the light-emitting layer 24. The reduction in abnormal light can reduce the area of the effective light-emitting region of the light-emitting element, and, furthermore, a drive voltage of the light-emitting element.

Assumed is a path through which the holes injected from the anode 10 travel across the hole transport layer 22 as indicated by an arrow E in FIG. 4, and reach the light-emitting layer 24. As to this path, the hole transport layer 22 has an effective thickness D2′ that is a thickness in a direction perpendicular to the side surface 12S of the edge cover 12. The effective thickness D2′ has a relationship of D2′=D2*cos T. In order to more reliably reduce the effective light emission area of the light-emitting element, the effective thickness D2′ of the hole transport layer 22 above the boundary line BL is preferably greater than the thickness D1 of the hole transport layer 22 (D1<D2′).

If a relationship of T≈50° holds, a relationship of cos 50°≈0.64 holds. Hence, a relationship of D1<D2*0.64 is preferable.

### Method for Manufacturing Display Device

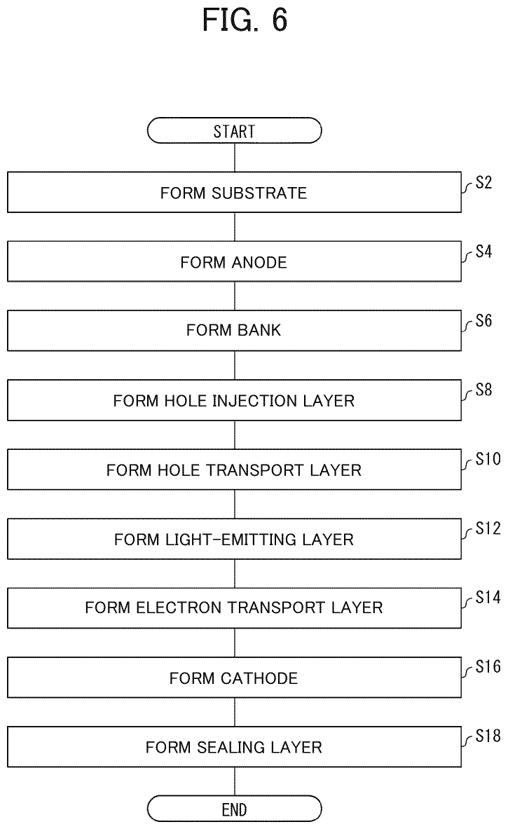

FIG. 6 is a schematic flowchart showing an example of a method for manufacturing the display device 2 according to this embodiment.

In the method for manufacturing the display device 2 according to this embodiment, first, the substrate 4 is formed (Step S2). The substrate 4 may be formed as follows: For example, on a hard glass substrate, a film base material is formed, and TFTs may be formed on the film base material. After that, the glass substrate is removed from the film base material. The removal of the glass substrate described above may be carried out after formation of the light-emitting element layer 6 and the sealing layer 8 to be described later. Alternatively, in forming the substrate 4, the TFTs may be directly formed on the hard glass substrate.

Next, on the substrate 4, the anode 10 is formed (Step S4). The anode 10 may be formed of, for example, a thin metal film deposited by such techniques as sputtering and vacuum evaporation. After that, the thin metal film is patterned by dry etching or wet etching with a photoresist to form the anode 10. Thus, on the substrate 4, the anode 10R, the anode 10G, and the anode 10B, each of which is shaped into an island shape, are formed for the respective subpixels.

Next, the edge cover 12 is formed (Step S6). At Step S6, the edge cover 12 is formed by photolithography of a positive photosensitive resin. Specifically, for example, a positive photosensitive resin to serve as a material of the edge cover 12 is applied to the upper surfaces of the substrate 4 and the anode 10. Next, a photomask, which has light-transmitting portions positioned for the respective subpixels, is placed above the applied photosensitive resin. Then, the photosensitive resin is irradiated with, for example, an ultraviolet ray through the photomask. Next, the photosensitive resin irradiated with the ultraviolet ray is rinsed with an appropriate developing solution. Thus, the edge cover 12 is formed between positions corresponding to the respective subpixels on the substrate 4.

Typically, the greater the distance is between the photomask and the object to be exposed to light, the smaller the light-exposure area is and the lower the light-exposure intensity is in plan view of the photomask. Thus, when the edge cover 12 is formed by photolithography of a positive photosensitive resin, the edge cover 12 is formed gradually smaller upwards from toward the substrate 4. Hence, at Step S6, the positive photosensitive resin is applied, exposed to light, and developed to form the edge cover 12. Such a feature can form the edge cover 12 whose side surface 20S is a forward-tapered surface.

Next, the hole injection layer 20 is formed (Step S8). In forming the hole injection layer 20, for example, an inorganic hole transporting material is dissolved in a solvent, and a first solution is obtained. Then, the first solution is applied to the edge cover 12 and the anode 10. The solvent is volatilized and removed with, for example, heat so that the first solution is solidified.

Next, the hole transport layer 22 is formed (Step S10). In forming the hole transport layer 22, for example, an organic hole transporting material is dissolved in a solvent, and a second solution is obtained. Then, the second solution is applied to the hole injection layer 20. The solvent is volatilized and removed with, for example, heat so that the second solution is solidified. Here, in order to achieve the above relationship D1<D2 by the meniscus effect with reference to FIG. 4, the second solution, which is a material of the hole transport layer 22, is required to have high wettability with respect to the hole injection layer 20. That is, the second solution is required to make contact with the hole injection layer 20 at an angle of smaller than 90°.

In this embodiment, each of the hole injection layer 20 and the hole transport layer 22 is formed in common to the plurality of light-emitting elements, and is not patterned. That is, each of the hole injection layer 20 and the hole transport layer 22 is also formed entirely on the side surface 12S and the upper surface 12U of the edge cover 12. Such a feature simplifies Steps S8 and S10, and reduces manufacturing costs of the light-emitting elements and the display device 2. In addition, the feature reduces performance deterioration observed in the hole transport material of the hole injection layer 20 and the hole transport layer 22 when the hole injection layer 20 and the hole transport layer 22 are patterned. An etching step, a rinsing step, and a resist layer for patterning deteriorate performance of the hole transporting material. Hence, the hole injection layer 20 and the hole transport layer 22 are high in performance, and the light-emitting elements included in the display device 2 are high in light emission efficiency.

As a typical tendency, it is understood that a light-emitting element included in the light-emitting element layer 6 is expected to emit more uniform light as each of the layers in the light-emitting element layer 6 has more uniform thickness. Hence, in known techniques, a solution is applied so that the thickness of the coating film is uniform. Specifically, when a known technique involves spin coating to apply the solution, the rotation speed is set to approximately 3000 rpm, and a volume density of the solute is set to approximately 6 mg/ml.

In contrast, the inventors of the present disclosure have found out that, as described before with reference to FIG. 4, the effective light emission area can be reduced when the hole transport layer 22 is not uniform and the relationship of D1<D2 holds. Hence, in forming the hole transport layer 22 according to this embodiment, the meniscus effect is enhanced.

Specifically, when Step S10 according to the present disclosure involves spin coating to apply the solution, the rotation speed is set to at least 2000 rpm or less, and, more preferably, at 1000 rpm or less. Additionally, or alternatively, as to the solution to be applied, the solute has a volume density of preferably 6 mg/ml or more, and, more preferably, 8 mg/ml or more.

Additionally, the larger the surface free energy of an underlayer is, the higher the wettability of the solution is with respect to the underlayer. Hence, the surface free energy of the hole injection layer 20 is preferably large. Specifically, the surface free energy is preferably 86 mNm/m or more. The numerical value 86 mNm/m represents a surface free energy of a clean silica glass. The unit mNm/m denotes milli-newton-meter per meter.

Next, the light-emitting layer 24 is formed (Step S12). The light-emitting layer 24 may be formed by any given technique. For example, the red light-emitting layer 24R may be formed and patterned by inkjet printing. Alternatively, for example, the red light-emitting layer 24R may be formed by an application technique using a spin coater, and patterned by photolithography. Alternatively, the red light-emitting layer 24R may be formed and patterned by evaporation using a fine metal mask (FMM).

Next, the electron transport layer 26 is formed (Step S14). In forming the electron transport layer 26, for example, an electron transporting material is dissolved in a solvent, and a third solution is obtained. Then, the third solution is applied to the light-emitting layer 24 and the hole transport layer 22. The solvent is volatilized and removed by, for example, heat so that the third solution is solidified. The electron transport layer 26 may be formed by another technique such as, for example, vacuum evaporation or sputtering.

Next, the cathode 16 is formed (Step S16). The cathode 16 can be formed of, for example, a thin metal film deposited by vacuum evaporation or sputtering. The thin metal film may be deposited in common to the subpixels to form the cathode 16. Thus, the formation of the light-emitting element layer 6 is completed.

Next, the sealing layer 8 is formed (Step S18). If the sealing layer 8 includes an organic sealing film, the organic sealing film may be formed by application of an organic sealing material. Furthermore, if the sealing layer 8 includes an inorganic sealing film, the inorganic sealing film may be deposited by, for example, the CVD. Hence, the sealing layer 8 is formed to seal the light-emitting element layer 6.

Then, as necessary, the glass substrate is removed, and a functional film is attached. As a result, the manufacturing of the display device 2 is completed. The functional film includes, for example, a polarizing plate film, a sensor film having a function of a touch sensor panel, a protective film, and an antireflection film.

### Advantageous Effects

Thanks to the configuration and the manufacturing method described above, the light-emitting layer 24 can be kept from emitting abnormal light; that is, emitting intense light in a ring shape above or nearly above the boundary line BL. The reduction in abnormal light can reduce the area of the effective light-emitting region of the light-emitting element, and, also, a drive voltage of the light-emitting element.

Thus, as to the display device 2 including a plurality of light-emitting elements according to the present disclosure, the effective light-emitting region is reduced in area so that the light-emitting elements are arranged at smaller spacings. Such a feature can enhance the definition of the display device 2. Furthermore, the feature reduces drive voltages of the light-emitting elements, thereby successfully reducing power consumption of the display device 2.

### Modifications

In the above description, the asperities on the edge cover 12 and the meniscus effect provide desired variations to the film thickness of the hole transport layer 22. However, the scope of the present disclosure shall not be limited to the above description.

For example, the asperities may be formed on any given bank. Here, the bank is a protruding portion formed at a peripheral edge portion of a light-emitting element, and shall not be limited in function. The bank may be partially formed at the peripheral edge portion of the light-emitting element. The bank may carry out any given function other than providing the asperities, either in conjunction with another constituent feature or alone. For example, in order to electrically separate the light-emitting elements from one another, the bank preferably exhibits lower electrical conductivity, and, more preferably, exhibits electrical insulation.

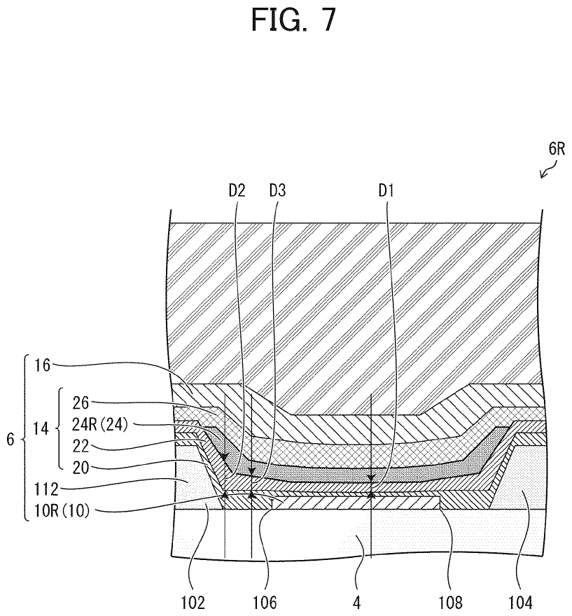

FIG. 7 is a cross-sectional view of a modification of a schematic configuration of the red light-emitting element 6R according to this embodiment.

The red light-emitting element 6R according to the modification illustrated in FIG. 7 includes: the anode 10R; a bank 112 having a first portion 102 and a second portion 104; the hole injection layer 20 formed at least partially on an upper surface of the anode 10R and a side surface of the bank 112; the hole transport layer 22 formed above the hole injection layer 20; the red light-emitting layer 24R formed above the hole transport layer 22; and the cathode 16 formed above the red light-emitting layer 24R. A first portion 102 of the bank 112 is spaced apart from, and adjacent to, a first end 106 of the anode 10R. A second portion 104 of the bank 112 is spaced apart from, and adjacent to, a second end 108 of the anode 10R across from the first end 106.

In the red light-emitting element 6R according to this modification, D1 represents a thickness of the hole transport layer 22 above the center of the anode 10R, and D2 represents a thickness of the hole transport layer 22 above a boundary line between the upper surface of the anode 10R and the side surface of the bank 112; that is, in this modification, above a boundary line between an upper surface of the substrate 4 and the side surface of the bank 112. In this configuration, a relationship of D1<D2 holds. Here, in a cross-section across the first portion 102 and the second portion 104 of the bank 112, the center of the anode 10R is in a middle of a line segment connecting together a lower end of the first portion 102 toward the anode 10R and a lower end of the second portion 104 toward the anode 10R.

The green light-emitting element 6G and the blue light-emitting element 6B can also be modified in the same manner as the red light-emitting element 6R.

As described above, the bank included in a light-emitting element according to the present disclosure includes: a first portion either adjacent to, or disposed above, a first end of the anode 10; and a second portion either adjacent to, or disposed above, a second end, of the anode 10, across from the first end. In the present disclosure, the term “adjacent” refers not only to a case where constituent features are adjacent to, and brought into contact with, each other, but also to a case where constituent features are adjacent to, and apart from, each other.

### Second Embodiment

Another embodiment of the disclosure will be described below. Note that, for convenience in description, like reference signs designate members having identical functions between this embodiment and the above embodiment. These members will not be elaborated upon repeatedly.

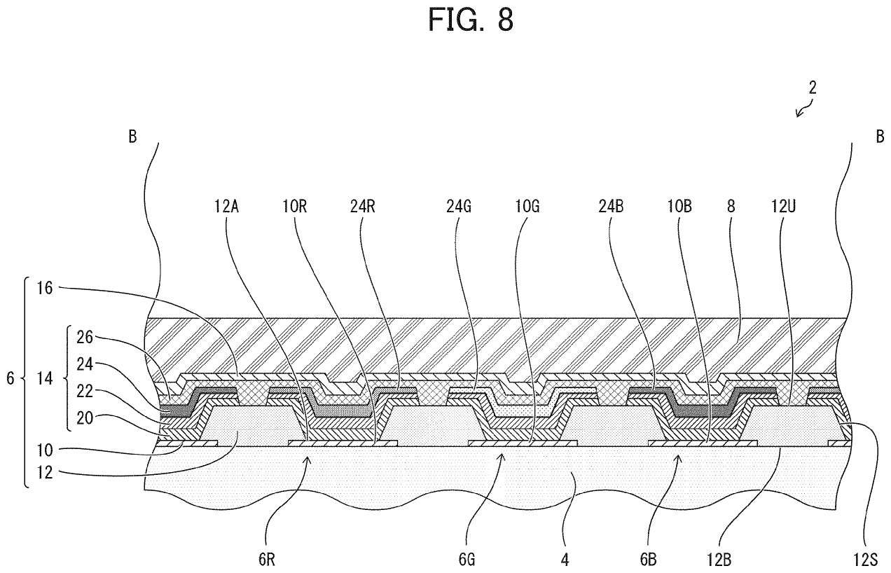

FIG. 8 is a partial cross-sectional view of an exemplary schematic configuration of the display region DA of the display device 2 according to an embodiment of the present disclosure.

As illustrated in FIG. 8, any one or more of the hole injection layer 20, the hole transport layer 22, and the electron transport layer 26 may be formed individually for each of the light-emitting elements. Hence, if the hole injection layer 20 covers only a portion, of the side surface 12S of the edge cover 12, close to the boundary line BL, such a configuration is included in the scope of the present disclosure. That is, in FIG. 8, the hole injection layer 20 is individually separated on the upper surface 12U of the edge cover for each light-emitting element. However, the present disclosure shall not be limited to such a configuration. The hole injection layer 20 may be individually separated on the side surface 12S of the edge cover 12 for each light-emitting element.

### Third Embodiment

Another embodiment of the disclosure will be described below. Note that, for convenience in description, like reference signs designate members having identical functions between this embodiment and the above embodiments. These members will not be elaborated upon repeatedly.

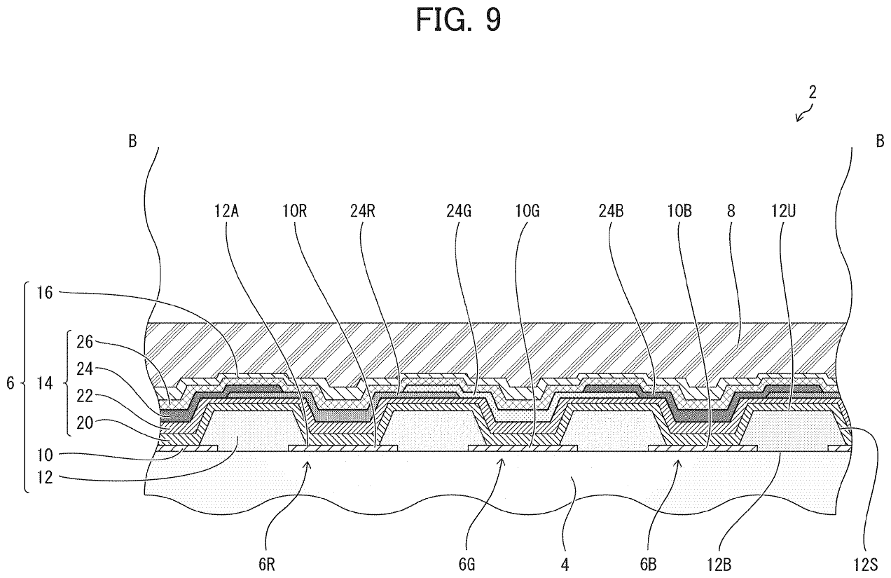

FIG. 9 is a partial cross-sectional view of an exemplary schematic configuration of the display region DA of the display device 2 according to an embodiment of the present disclosure.

As illustrated in FIG. 9, the red light-emitting layer 24R, the green light-emitting layer 24G, and the blue light-emitting layer 24B may be formed to overlap with one another. Hence, if the electron transport layer 26 and the hole transport layer 22 are not in direct contact with each other, such a configuration is included in the scope of the present disclosure.

Furthermore, FIG. 9 shows that, on the upper surface 12U of the edge cover 12, a light-emitting layer is formed to overlap with another light-emitting layer. However, the present disclosure shall not be limited to such a configuration. On the side surface 12S of the edge cover 12, a light-emitting layer may be formed to overlap with another light-emitting layer.

Moreover, only on the upper surface 12U of the edge cover 12, a light-emitting layer may be formed to overlap with another light-emitting layer.

Here, described below will be a thickness of the hole transport layer 22 and a luminance-voltage characteristic (hereinafter referred to as an “L-V characteristic”) of the light-emitting element layer 6.

### First Example

### Manufacturing Step

In a first example, first, an ITO film having an area of 2 mm*10 mm was formed by sputtering on the substrate 4 to serve as the anode 10 (Step S4).

In the first example, the edge cover 12 was not formed. That is, in order to clarify a relationship between the thickness of the hole transport layer 22 and the L-V characteristic, each layer was formed flat.

Next, 249 mg of nickel acetate was dissolved in 5 ml of ethanol, and 0.1 ml of a nickel acetate solution was applied to the ITO film by spin coating. The ITO film was heated at 230° C. for 1 hour in the atmosphere (Step S8). Hence, a nickel oxide film was formed as the hole injection layer 20.

Next, MeO-2PACz was dissolved in ethanol so that a solution was prepared to have a concentration of 0.01 mol/l. The MeO-2PACz solution was applied to the nickel oxide film. After 5 seconds or more, the MeO-2PACz solution was dried. Hence, a SAM was formed on the surface of the nickel oxide film.

Next, 4 mg of p-TPD was dissolved in 1 ml of chlorobenzene, and the p-TPD solution was applied to the SAM by spin coating (Step S10). The rotation speed was 2000 rpm. Hence, a p-TPD film was formed as the hole transport layer 22.

Next, 1 ml of a solution containing quantum dots each having a core-shell structure of CdSe and ZnS was applied to the p-TPD film by spin coating, and dried (Step S12). Thus, the light-emitting layer 24 was formed.

Next, a solution containing ZnO nanoparticles having a particle size of 12 nm was applied to the light-emitting layer 24 by spin coating, and dried (Step S14). Hence, a ZnO nanoparticle film was formed as the electron transport layer 26.

Next, an Al electrode was deposited on the ZnO nanoparticle film by vacuum evaporation (Step S16). Hence, the Al electrode was obtained as the cathode 16.

As can be seen, the light-emitting element layer 6 according to the first example was formed. Here, the hole injection layer 20 had a thickness of approximately 45 nm, and the hole transport layer 22 had a thickness of approximately 20 nm. As will be described later for the first example, the thickness is a thickness of each of the layers formed above the center portion of the anode 10. The thickness is measured by observation of the cross-section with a SEM.

### Second Example

In a second example, the light-emitting element layer 6 was formed in the same manner as in the first example except that the amount of the p-TPD at Step S10 of the first example was set to 8 mg. Here, the hole injection layer 20 had a thickness of approximately 45 nm, and the hole transport layer 22 had a thickness of approximately 37 nm.

### Third Example

In a third example, the light-emitting element layer 6 was formed in the same manner as in the first example except that the amount of the p-TPD at Step S10 of the first example was set to 12 mg. Here, the hole injection layer 20 had a thickness of approximately 45 nm, and the hole transport layer 22 had a thickness of approximately 65 nm.

### Fourth Example

In a fourth example, the light-emitting element layer 6 was formed in the same manner as in the second example except that the amount of the nickel acetate at Step S8 of the second example was set to 622 mg. Here, the hole injection layer 20 had a thickness of approximately 107 nm, and the hole transport layer 22 had a thickness of approximately 37 nm.

### Fifth Example

In a fifth example, the light-emitting element layer 6 was formed in the same manner as in the third example except that the amount of the nickel acetate at Step S8 of the third example was set to 622 mg. Here, the hole injection layer 20 had a thickness of approximately 107 nm, and the hole transport layer 22 had a thickness of approximately 65 nm.

### Measuring Voltage and Luminance

For each light-emitting element layer 6 of the first to fifth examples, a voltage E (V) was applied between the anode 10 and the cathode 16, and a current density J (mA/cm²) with respect to the voltage E (V) was measured for a current flowing between the anode 10 and the cathode 16. Furthermore, a luminance value L (cd/m²) with respect to the voltage E (V) was measured for the light-emitting element layer 6, using an LED measuring apparatus. The LED measuring apparatus was a spectrometer.

Note that the voltage E (V) was measured within a range from 0 V to a voltage value raised to the degree that the current density J (mA/cm²) exceeded 50 mA/cm².

### Results

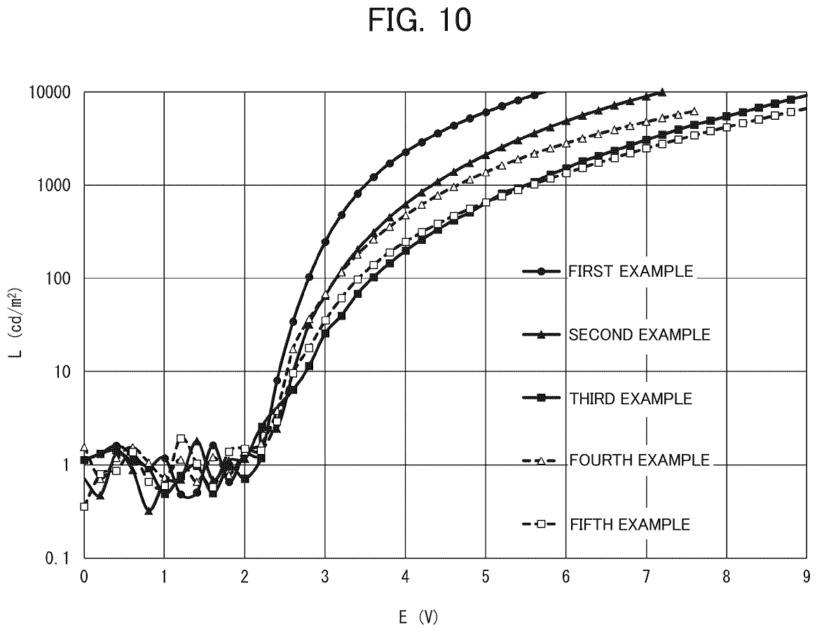

FIG. 10 is a graph showing results of measuring voltage and luminance in the light-emitting element layer 6 of each of the first to fifth examples.

FIG. 10 shows that, as to a voltage required to obtain the same luminance, the difference in the required voltage was small between the second example and the fourth example, and between the third example and the fifth example. Whereas, the difference in the required voltage was large between the first example, the second example, and the third example, and between the fourth example and the fifth example.

As described above, the hole injection layers 20 were different in thickness, and the hole transport layers 22 were the same in thickness, between the second example and the fourth example, and between the third example and the fifth example. Whereas, the hole injection layers 20 were the same in thickness, and the hole transport layers 22 were different in thickness, between the first example, the second example, and the third example, and between the fourth example and the fifth example.

Hence, the variation in the thickness of the hole injection layers 20 has a small influence on the L-V characteristic of the light-emitting element. Whereas, the variation in the thickness of the hole transport layers 22 has a large influence on the L-V characteristic of the light-emitting element.

As shown in FIG. 10, the thicker the hole transport layer 22 is according to the first to fifth examples, the larger the voltage to be required is to obtain the same luminance. While the light-emitting element is driven, the hole injection layer 20 and the hole transport layer 22 are in a state of a space-charge limited current region. Hence, an equation below is given.

$$I = \frac{9}{8} * \frac{εμ {V}^{2}}{{d}^{3}} \qquad [ Math . 1 ]$$

Wherein:
I represents a value of a current flowing in the light-emitting element layer 6;
V represents a value of a voltage applied to the light-emitting element layer 6;
ε represents a relative permittivity of the hole transport layer 22;
μ represents a mobility of the holes in the hole transport layer 22; and
d represents a thickness of the hole transport layer 22 above the center portion of the anode 10.

For obtaining a resistance value of the hole transport layer 22, the above equation is differentiated by the current value I. Hence, an equation below is given.

$$\frac{dV}{dI} = \frac{4}{9} * \frac{{d}^{3}}{εμV} \qquad [ Math . 2 ]$$

Hence, regardless of a material of the hole transport layer 22, the resistance value; that is, the voltage-current ratio (dV/dI) is proportional to the third power (d³) of the thickness of the hole transport layer 22. That is, an effective light-emitting region of a light-emitting element having the edge cover 12 and the area of the effective light-emitting region are influenced by the distribution of the thickness of the hole transport layer 22 regardless of the material of the hole transport layer 22.

In the configuration according to the present disclosure, the hole transport layer 22 is formed on the non-flat surface resulting from the edge cover 12. That is why the hole transport layer 22 is not uniform in thickness. That is, the effective light-emitting region of the light-emitting element having the edge cover 12 and the area of the effective light-emitting region are influenced by the distribution of the thickness of the hole transport layer 22.

Hence, beneficially, the hole transport layer 22 is: formed thick in a region where emission of light is not desirable; and formed thin in a region where emission of light is desirable. Specifically, in order to reduce the effective light emission area of the light-emitting element, the hole transport layer is beneficially formed thick above the boundary line BL, and near the boundary line BL (particularly, in an outward position away from the boundary line BL).

### First Example

Described below will be an example of the first embodiment of the present disclosure.

### Manufacturing Step

First, TFTs were formed on the substrate 4 (Step S2), and a multilayer film of IZO and Ag was formed as the anode 10 by sputtering (Step S4).

Next, the edge cover 12 was formed of polyimide (Step S6). The opening 12A of the edge cover 12 was shaped into an oval shape in which a semicircle was added to each short side of a rectangle.

Next, 249 mg of nickel acetate was dissolved in 5 ml of ethanol, and 0.1 ml of a nickel acetate solution was applied to the multilayer film of IZO and Ag by spin coating. The multilayer film was heated at 230° C. for 1 hour in the atmosphere (Step S8). Hence, a nickel oxide film was formed as the hole injection layer 20.

Next, p-nitrobenzoic acid was dissolved in methanol so that a solution was prepared to have a concentration of 0.01 mol/l. The solution of p-nitrobenzoic acid was applied to the nickel oxide film. After 5 seconds or more, the solution of p-nitrobenzoic acid was dried. Hence, a SAM was formed on the surface of the nickel oxide film.

Next, 8 mg of TFB was dissolved in 1 ml of chlorobenzene, and the TFB solution was applied to the SAM by spin coating (Step S10). The rotation speed was 2000 rpm. Hence, a TFB film was formed as the hole transport layer 22.

Next, 1 ml of a solution containing quantum dots each having a core-shell structure of CdSe and ZnS was applied to a p-TPD film by spin coating, and dried (Step S12). Thus, the light-emitting layer 24 was formed.

Next, a solution containing ZnO nanoparticles having a particle size of 12 nm was applied to the light-emitting layer 24 by spin coating, and dried (Step S14). Hence, a ZnO nanoparticle film was formed as the electron transport layer 26.

Next, an Ag electrode was deposited on the ZnO nanoparticle film by vacuum evaporation (Step S16). Hence, the Ag electrode was obtained as the cathode 16.

As can be seen, the light-emitting element layer 6 according to the first example was formed.

Observation of Cross-Section with SEM

After the measurement of voltage and luminance, the light-emitting element layer 6 of the first example was cut along a plane running across the longitudinal center of the opening 12A of the edge cover 12, perpendicularly to the upper surface of the anode 10 in a transverse direction of the opening 12A. Then, the cutting plane was observed, using a scanning electron microscope (SEM).

A schematic configuration of the light-emitting element layer 6 according to the first example was the same as the schematic configuration illustrated in FIG. 3 except that the light-emitting layer 24 was a single layer formed in common to a plurality of light-emitting elements.

The anode 10; namely, the multilayer film of IZO and Ag, had a substantially uniform thickness of approximately 100 nm.

A distance of approximately 30 μm was kept between the boundary points BP facing each other across the opening 12A of the edge cover 12. Hence, a point that was 15 to 17 μm away from the boundary points BP was defined as a transverse center portion of the opening 12A. The edge cover 12 had a tilt angle T of approximately 32°. Note that, as described above with reference to FIG. 5, the tilt angle T was an angle between the line segment L1 passing through the upper end point 30 200 nm away from the boundary point BP and the line segment L2 passing through the lower end point 32 200 nm away from the boundary point BP.

The hole injection layer 20; namely, the nickel oxide film, had a thickness of approximately 45 nm in the transverse center portion of the opening 12A of the edge cover 12.

The hole transport layer 22; namely, the TFB film, had: a thickness D1 of approximately 30 nm in the transverse center portion of the opening 12A of the edge cover 12; and a thickness D3 of approximately 70 nm positioned approximately 1 μm inward away from the boundary line BL.

The light-emitting layer 24 had a thickness of approximately 15 nm in the transverse center portion of the opening 12A of the edge cover 12.

The electron transport layer 26; namely, the ZnO nanoparticle film, had a thickness of approximately 45 nm in the transverse center portion of the opening 12A of the edge cover 12.

The cathode 16, that is, the Ag electrode, had a substantially uniform thickness of approximately 15 nm. Hence, the Ag electrode was sufficiently thin, and served as a transparent electrode transparent to light.

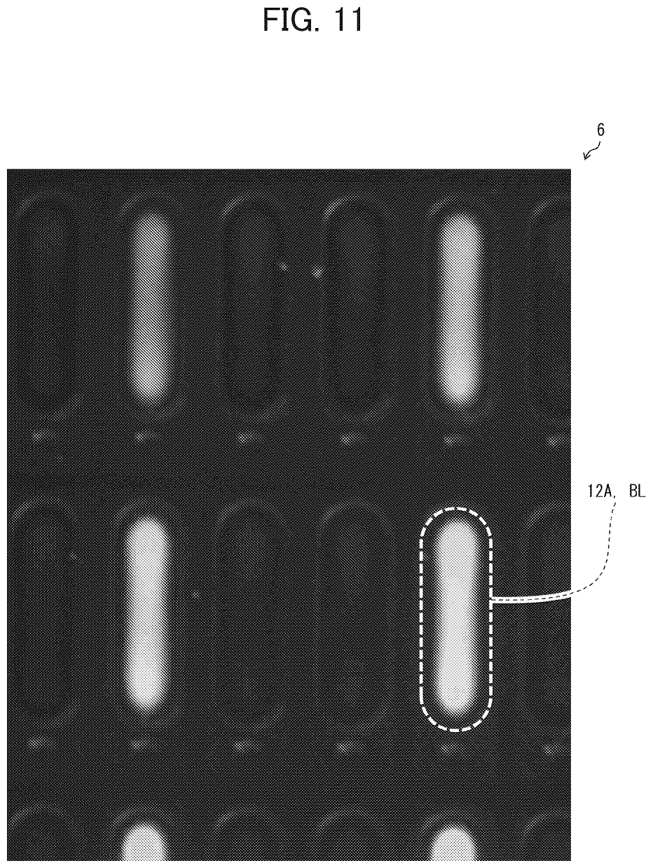

FIG. 11 is a photograph taken when the light-emitting element layer 6 of the first example according to the first embodiment of the present disclosure emits light.

FIG. 11 shows that, in the light-emitting element layer 6 of the first example, the effective light-emitting region of the light-emitting element is smaller than the opening 12A of the edge cover 12. The opening 12A is a region surrounded with the boundary line BL. In the light-emitting element layer 6 of the first example, D1 is approximately 30 nm and D3 is approximately 70 nm. A relationship of 70=30*2.3+1 holds. Hence, it is assumed that the hole transport layer 22 is preferably formed to have a relationship of D1*2.3<D3.

The disclosure shall not be limited to the embodiments described above, and can be modified in various manners within the scope of claims. The technical aspects disclosed in different embodiments are to be appropriately combined together to implement an other embodiment. Such an embodiment shall be included within the technical scope of the disclosure. Moreover, the technical aspects disclosed in each embodiment may be combined to achieve a new technical feature.

1. A light-emitting element, comprising:
an anode;
a bank at least partially adjacent to, or disposed above, the anode;
a hole injection layer formed at least partially on an upper surface of the anode and a side surface of the bank;
a hole transport layer formed above the hole injection layer;
a light-emitting layer formed above the hole transport layer; and
a cathode formed above the light-emitting layer,
wherein if, as to thicknesses in a direction perpendicular to the upper surface of the anode, the hole transport layer has: a thickness D1 above a center of the anode; and a thickness D2 above a boundary line between the upper surface of the anode and the side surface of the bank,
a relationship of D1<D2 holds.

2. The light-emitting element according to claim 1,
wherein the bank has a tilt angle T, and
a relationship of D1<D2*cos T holds.

3. The light-emitting element according to claim 2,
wherein the tilt angle T has a relationship of 0°<T<50°.

4. The light-emitting element according to claim 1,
wherein if, as to a thickness in the direction perpendicular to the upper surface of the anode, the hole transport layer has a thickness D3 1 μm inward away from above the boundary line of the hole transport layer,
a relationship of D1*2.3<D3 holds.

5. The light-emitting element according to claim 1,
wherein the hole injection layer contains an inorganic hole transport material.

6. The light-emitting element according to claim 5,
wherein the inorganic hole transport material is a metal oxide.

7. The light-emitting element according to claim 1,
wherein the hole injection layer has an electrical resistivity of 1*10⁶ Ωcm or more.

8. The light-emitting element according to claim 1,
wherein the light-emitting layer contains quantum dots.

9. A light-emitting element, comprising:
a first electrode;
a bank at least partially either adjacent to the first electrode, or disposed above the first electrode;
a first layer containing an inorganic hole transport material, and formed at least partially on an upper surface of the first electrode and a side surface of the bank;
a second layer containing an organic hole transport material, and formed above the first layer;
a light-emitting layer formed above the second layer; and
a second electrode formed above the light-emitting layer,
wherein if, as to thicknesses in a direction perpendicular to the upper surface of the first electrode, the second layer has: a thickness D1 above a center of the first electrode; and a thickness D2 above a boundary line between the upper surface of the first electrode and the side surface of the bank,
a relationship of D1<D2 holds.

10. A display device comprising the light-emitting element according to claim 1.

11. A display device, comprising
a plurality of the light-emitting elements according to claim 1,
wherein each of the hole injection layer and the hole transport layer is formed in common to the plurality of light-emitting elements.

12. A method for manufacturing a light-emitting element, comprising steps of:
(a) forming an anode;
(b) forming a bank at least partially adjacent to, or disposed above, the anode;
(c) forming a hole injection layer at least partially on an upper surface of the anode and a side surface of the bank;
(d) forming a hole transport layer above the hole injection layer;
(e) forming a light-emitting layer above the hole transport layer; and
(f) forming a cathode above the light-emitting layer,
wherein if, as to thicknesses in a direction perpendicular to the upper surface of the anode, the hole transport layer has: a thickness D1 above a center of the anode; and a thickness D2 above a boundary line between the upper surface of the anode and the side surface of the bank,
step (d) involves forming the hole transport layer so that a relationship of D1<D2 holds.

13. The method for manufacturing the light-emitting element according to claim 12,
wherein step (d) includes steps of:
(g) applying a solution to the hole injection layer; and
(h) solidifying the solution,
wherein, at step (g), the solution makes contact with the hole injection layer at an angle of smaller than 90°.

14. The method for method for manufacturing the light-emitting element according to claim 13,
wherein the solution is prepared so that a solute of the solution has a volume density of 6 mg/ml or more.

15. The method for manufacturing the light-emitting element according to claim 13,
wherein the solution is prepared so that a solute of the solution has a volume density of 8 mg/ml or more.

16. The method for manufacturing the light-emitting element according to claim 13,
wherein, at step (g), the solution is applied by spin coating at a rotation speed of 2000 rpm or less.

17. The method for manufacturing the light-emitting element according to claim 13,
wherein, at step (g), the solution is applied by spin coating at a rotation speed of 1000 rpm or less.
